(19) United States
(12) Patent Application Publication
(10) Pub. No.: US 2023/0300989 A1
(43) Pub. Date: Sep. 21, 2023

(54) CIRCUIT BOARD ETCHING DEVICE AND METHOD FOR IMPROVING ETCHING FACTOR

(71) Applicant: TEMG TAI PCB MACHINERY CO., LTD., TAO YUAN CITY (TW)

(72) Inventors: PATRICK LU, TAO YUAN CITY (TW); CHIH WEI LU, TAO YUAN CITY (TW)

(21) Appl. No.: 18/046,742

(22) Filed: Oct. 14, 2022

(30) Foreign Application Priority Data
Mar. 15, 2022 (TW) 111109499

(51) Int. Cl. H05K 3/06; H05K 3/00

(52) U.S. Cl. CPC H05K 3/068; H05K 3/002; H05K 2203/0195; H05K 2203/0165

(57) ABSTRACT

A circuit board etching device for improving etching factor, comprising: a circuit board conveying device, which laterally conveys a circuit board; a circuit forming etching tank and a first etchant spraying unit, the first etchant spraying unit sprays a first etchant on the etching surface of the circuit board; and a circuit modification etching tank and a second etchant spraying unit, the second etchant spraying unit sprays a second etchant on the etching surface of the circuit board, and make the etching speed of the circuit modification etching tank slower than the etching speed of the circuit forming etching tank, whereby having the effect of improving the etching factor of the circuit board

### BACKGROUND OF THE INVENTION

### 1. Field of the Invention

The invention relates to a circuit board etching device and method for improving etching factor, especially to a circuit board circuit etching process firstly perform the circuit forming etching stage and then the circuit modification etching stage, and the etching speed of the circuit modification etching stage is slower than the etching speed of the circuit forming etching stage.

### 2. Description of the Related Art

Taiwan Patent No. 1539876 disclosed an etching method and device, which spray an etchant through a fluid nozzle on the etching object surface of the etching object, so as to perform the first etching process of etching the etching object surface; and mixing the etchant with the gas and spraying it from a two-fluid nozzle, blowing the etchant on the etching object surface etched in the first etching process, thereby further etching the etching object surface in the second etching process; In the second etching process, the etchant with smaller droplets is blown onto the etching object surface with a stronger impact force than that in the first etching process.

In order to improve the circuit board circuit etching factor, the complete circuit board circuit etching process should be divided into two etching stages: “circuit forming” and “circuit modification”; however, as prior art disclosed, the industry currently uses etchants with the same etching speed for processing and production, and the etching process of circuit board circuits is not divided into two etching stages: “circuit forming” and “circuit modification”, and because the “circuit forming” stage requires the use of an etchant with a fast etching speed, but in the “circuit forming” stage, if the etchant with a fast etching speed is used in the “circuit modification” stage, it is difficult to control the undercut, and there is a concern that the circuit etch factor (E/F) may not meet the design requirements.

### SUMMARY OF THE INVENTION

It is a primary objective of the present invention is to solve the problem that the circuit etching factor may not meet the design requirements in the prior art, and has the effect of improving the circuit etching factor of the circuit board.

In order to achieve the above objectives, the present invention comprise: a circuit board conveying device, which laterally conveys the circuit boards to be etched; a circuit forming etching tank is arranged in the front section of the circuit board conveying device, and a first etchant spraying unit is arranged relatively to the circuit board conveying device, the first etchant spraying unit sprays a first etchant on the etching surface of the circuit board; and a circuit modification etching tank is arranged in the rear section of the circuit board conveying device, and a second etchant spraying unit is arranged relatively to the circuit board conveying device, the second etchant spraying unit sprays a second etchant on the etching surface of the circuit board, and make the etching speed of the circuit modification etching tank slower than the etching speed of the circuit forming etching tank.

Moreover, the etching speed of the second etchant is slower than the etching speed of the first etchant, and make the etching speed of the circuit modification etching tank slower than the etching speed of the circuit forming etching tank; or, the spray flow rate of the second etchant spraying unit is smaller than the spray flow rate of the first etchant spraying unit, and the impact force of the board surface generated by the second etchant spraying unit is greater than the board surface impact force generated by the first etchant spraying unit, so that the etching speed of the circuit modification etching tank is slower than the etching speed of the circuit forming etching tank.

Also, the circuit board conveying device horizontally and laterally conveys the circuit board, the circuit forming etching tank is provided with a first etchant suction unit above the circuit board conveying device, and the circuit modification etching tank is provided with a second etchant suction unit above the circuit board conveying device; wherein the first etchant spraying unit is provided with a plurality of first etchant spraying nozzles above and below the circuit board conveying device, and the first etchant is pumped from the bottom of the circuit forming etching tank by a first etchant pump, then a first etchant delivery pipe conveys the first etchant to each of the first etchant spraying nozzles; the second etchant spraying unit is provided with a plurality of second etchant spraying nozzles above and below the circuit board conveying device, and the second etchant is pumped from the bottom of the circuit modification etching tank by a second etchant pump, then a second etchant delivery pipe conveys the second etchant to each of the second etchant spraying nozzles; the first etchant suction unit is provided with a plurality of first etchant suction nozzles above the circuit board conveying device, and uses the first etchant pump to make a first ejector of a first etchant suction pipe generates negative pressure, and then the first etchant suction nozzle of the first etchant suction pipe sucks the first etchant on the surface of the circuit board back to the bottom of the circuit forming etching tank; the second etchant suction unit is provided with a plurality of second etchant suction nozzles above the circuit board conveying device, and uses the second etchant pump to make a second ejector of a second etchant suction pipe generates negative pressure, and then the second etchant suction nozzle of the second etchant suction pipe sucks the second etchant on the surface of the circuit board back to the bottom of the circuit modification etching tank.

Also, further make the second etchant spraying nozzle located in the rear section of the circuit modification etching tank adopts a second etchant spraying nozzle mixed with high-pressure gas, and the high-pressure gas of a high-pressure gas source is transported by a high-pressure gas delivery pipe to each second etchant spraying nozzle mixed with high-pressure gas, the second etchant particles are smaller due to the mixing of high-pressure gas and improve the impact force of the board surface; wherein the ratio of the spray amount of the second etchant mixed with high-pressure gas to the total spray amount of the second etchant is greater than 60%, and the etching stroke of the circuit modification etching tank is 20-100% of the etching stroke of the circuit forming etching tank.

In addition, the circuit board etching method for improving etching factor make the circuit board circuit etching process first perform the circuit forming etching stage, then perform the circuit modification etching stage, and the etching speed of the circuit modification etching stage is slower than the etching speed of the circuit forming etching stage; wherein the etching speed of the etchant sprayed in the circuit modification etching stage is slower than the etching speed of the etchant sprayed in the etching forming etching stage, so that the etching speed of the circuit modification etching stage is slower than the etching speed of the circuit forming etching stage; or, the spray rate of the sprayed etchant of the circuit modification etching stage is smaller than the spray rate of the sprayed etchant of the circuit forming etching stage, and the impact force of the board surface adopted in the circuit modification etching stage is greater than the impact force of the board surface adopted in the circuit forming etching stage, so that the etching speed of the circuit modification etching stage is slower than the etching speed of the circuit forming etching stage.

Also, the circuit board is horizontally and laterally conveyed, the etchant on the surface of the circuit board is immediately sucked, and the etchant sprayed in the latter section of the circuit modification etching stage is mixed with high-pressure gas; wherein the ratio of the spray amount of the etchant mixed with high pressure gas of the circuit modification etching stage to the total spray amount of the circuit modification etching stage is at least 60%, and the etching stroke of the circuit modification etching stage is 20-100% of the etching stroke of the circuit forming etching stage.

### BRIEF DESCRIPTION OF THE DRAWINGS

FIG. 1 is a schematic diagram illustrating structure of the present invention.

### DETAILED DESCRIPTION OF THE PREFERRED EMBODIMENT

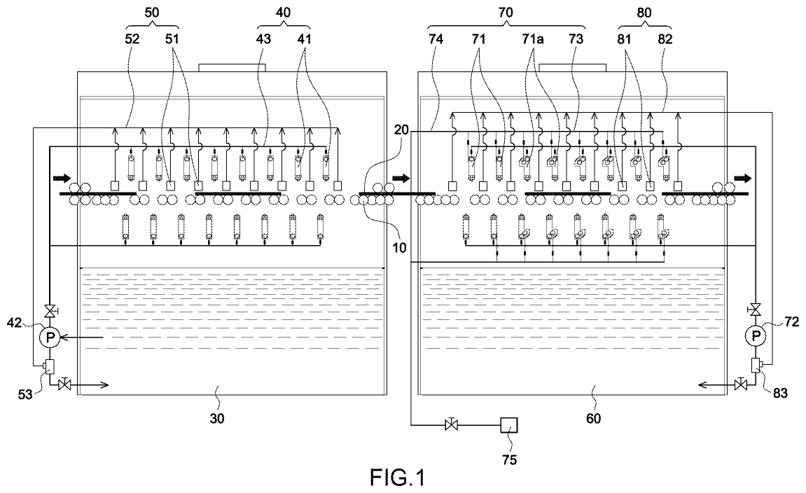

Referring to FIG. 1, the present invention, including: a circuit board conveying device 10, which laterally conveys a circuit board 20 to be etched; a circuit forming etching tank 30 is arranged in the front section of the circuit board conveying device 10, and a first etchant spraying unit 40 is arranged relatively to the circuit board conveying device 10, the first etchant spraying unit 40 sprays a first etchant on the etching surface of the circuit board 20, the first etchant spraying unit 40 is provided with a plurality of first etchant spraying nozzles 41 above and below the circuit board conveying device 10, and the first etchant is pumped from the bottom of the circuit forming etching tank 30 by a first etchant pump 42, then a first etchant delivery pipe 43 conveys the first etchant to each of the first etchant spraying nozzles 41; the first etchant suction unit 50 is provided with a plurality of first etchant suction nozzles 51 above the circuit board conveying device 10, and uses the first etchant pump 42 to make a first ejector 53 of a first etchant suction pipe 52 generates negative pressure, and then the first etchant suction nozzle 51 of the first etchant suction pipe 52 sucks the first etchant on the surface of the circuit board 20 back to the bottom of the circuit forming etching tank 30; and a circuit modification etching tank 60 is arranged in the rear section of the circuit board conveying device 10, and a second etchant spraying unit 70 is arranged relatively to the circuit board conveying device 10, the second etchant spraying unit 70 sprays a second etchant on the etching surface of the circuit board 20, and make the etching speed of the circuit modification etching tank 60 slower than the etching speed of the circuit forming etching tank 30, the second etchant spraying unit 70 is provided with a plurality of second etchant spraying nozzles 71 above and below the circuit board conveying device 10, and the second etchant is pumped from the bottom of the circuit modification etching tank 60 by a second etchant pump 72, then a second etchant delivery pipe 73 conveys the second etchant to each of the second etchant spraying nozzles 71; the second etchant suction unit 80 is provided with a plurality of second etchant suction nozzles 81 above the circuit board conveying device 10, and uses the second etchant pump 72 to make a second ejector 83 of a second etchant suction pipe 82 generates negative pressure, and then the second etchant suction nozzle 81 of the second etchant suction pipe 82 sucks the second etchant on the surface of the circuit board 20 back to the bottom of the circuit modification etching tank 60.

Moreover, the etching speed of the second etchant is slower than the etching speed of the first etchant, and make the etching speed of the circuit modification etching tank 60 slower than the etching speed of the circuit forming etching tank 30; or, the spray flow rate of the second etchant spraying unit 70 is smaller than the spray flow rate of the first etchant spraying unit 40, and the impact force of the board surface generated by the second etchant spraying unit 70 is greater than the board surface impact force generated by the first etchant spraying unit 40, so that the etching speed of the circuit modification etching tank 60 is slower than the etching speed of the circuit forming etching tank 30, and the etching stroke of the circuit modification etching tank 60 is 20-100% of the etching stroke of the circuit forming etching tank 30; also, further make the second etchant spraying nozzle 71 located in the rear section of the circuit modification etching tank 60 adopts a second etchant spraying nozzle mixed with high-pressure gas 71a, and the high-pressure gas of a high-pressure gas source 75 is transported by a high-pressure gas delivery pipe 74 to each second etchant spraying nozzle mixed with high-pressure gas 71a, the second etchant particles are smaller due to the mixing of high-pressure gas and improve the impact force of the board surface; wherein the ratio of the spray amount of the second etchant mixed with high-pressure gas to the total spray amount of the second etchant is greater than 60%.

With the features disclosed above, the present invention first performs the circuit forming etching stage in the circuit forming etching tank 30, and then performs the circuit modification etching stage (circuit modification and bottom copper cleaning) in the circuit modification etching tank 60, and divide circuit etching into two etching stages: “circuit forming” and “circuit modification”; In the “circuit forming” etching stage, the first etchant with a large erosion rate is used, or/and the spray flow rate generated by the first etchant spraying nozzles 41 is large and the impact force on the board surface is small, which can increase the output and reduce the cost, and can be matched with the first etchant suction unit 50 to avoid pool effect; In the “circuit modification” etching stage, the second etchant with a small erosion rate (compared with the first etchant) is used, or/and the spray flow rate generated by the second etchant spraying nozzles 71 is small (compared with the first etchant spraying nozzles 41) and the impact force on the board surface is large (compared with the impact force generated by the first etchant spraying nozzles 41), performing rough circuit modification, and then use the second etchant spraying nozzle mixed with high-pressure gas 71a to make the sprayed second etchant particles smaller and more impactful, so as to carry out detailed circuit modification, reduce the amount of undercut erosion and bottom residue copper, and improve circuit board circuit etching factor, and can be matched with the second etchant suction unit 80 to avoid pool effect.

However, the control of the etching speed can be adjusted by reducing the spray flow of the etchant or changing the parameters of the etchant: Acid etching parameters like temperature/hydrochloric acid/oxidant/copper concentration (specific gravity) is adjusted, when high temperature, high hydrochloric acid concentration (high acid), low copper concentration (specific gravity), the etching speed is fast (large erosion rate), and when low temperature, low hydrochloric acid concentration (low acid), the concentration of copper (specific gravity) is high, and the etching speed is slow (small erosion rate); or adding additives (etch inhibitor/banking agent) can also reduce the etching speed and reduce undercut. Furthermore, the control of the etching speed can also be adjusted through the mechanism: 1. Large spray flow/high pressure (large impact force), fast etching speed (large erosion rate); 2. Small spray flow/low pressure (small impact force), slow etching speed (small erosion rate); 3. The closer the nozzle is to the height of the board, the greater the impact on the board.

Therefore, the parameters of the etchant in the two etching stages of “circuit forming” and “circuit modification” are different, they are controlled separately, and the etchants are not connected and not shared; in the “circuit forming” stage, the etching treatment has a large erosion rate, and the sprayed etchant only need to configure general spray and suction devices, and the etchant is set with parameters of fast etching speed; in the “circuit modification” stage, the etchant is set with parameters of slow etching speed (or reducing the spray flow of the etchant, or adding etching banking agent), under the condition of reducing the etching speed and increasing the impact force of the board can modify the circuit and the bottom copper cleaning, the methods of increasing the impact force of the board surface include increasing the spray pressure or reducing the height of the nozzle from the board surface, and first perform rough circuit modification with a small erosion rate, then use mixed high-pressure gas to spray the etchant or reduce the height of the nozzle from the board surface to increase the impact force of the board surface, so that the etchant can more easily enter the gap and bottom of the thin circuit, perform detailed circuit modification to clean bottom copper residues and reduce undercut.

The test results of the present invention are as follows: it shows that the etching factor can be increased by using different parameters of the etchant in the two etching stages of circuit forming/circuit modification, and the etching factor can be increased by adding additives in the circuit modification etching stage, and increase the ratio of used of etchant spraying nozzle mixed with high-pressure gas during the circuit modification etching stage can improve the etching factor.

| | | | Circuit |
|---|---|---|---|
| The ratio of the | E/F | | forming/circuit |
| spray amount of | 18 μm copper | | modification |
| the second | thickness, | | etchant with |
| etchant mixed | 20/20 μm circuit | Circuit | the different |
| with high- | Circuit | forming/circuit | parameters |
| pressure gas to | forming/circuit | modification | (circuit |
| the total spray | modification | etchant with | modification |
| amount of the | etchant with the | the different | adding with |
| second etchant | same parameters | parameters | additives) |
| 20% | 3.2 | 3.6 | 3.8 |
| 40% | 3.8 | 4.2 | 4.5 |
| 60% | 5.8 | 6.3 | 6.6 |
| 80% | 6.5 | 7.5 | 7.9 |
| 100% | 7.5 | 8.6 | 9.2 |

| | | | Circuit |
|---|---|---|---|
| The ratio of the | E/F | | forming/circuit |
| spray amount of | 35 μm copper | | modification |
| the second | thickness, | | etchant with |
| etchant mixed | 50/25 μm circuit | Circuit | the different |
| with high- | Circuit | forming/circuit | parameters |
| pressure gas to | forming/circuit | modification | (circuit |
| the total spray | modification | etchant with | modification |
| amount of the | etchant with the | the different | adding with |
| second etchant | same parameters | parameters | additives) |
| 20% | 3.0 | 3.2 | 3.5 |
| 40% | 3.2 | 3.7 | 3.9 |
| 60% | 5.6 | 6.1 | 6.5 |
| 80% | 6.6 | 7.5 | 7.9 |
| 100% | 7.3 | 8.5 | 9.1 |

Therefore, the circuit board etching method for improving etching factor make the circuit board circuit etching process first perform the circuit forming etching stage, then perform the circuit modification etching stage, and the etching speed of the etchant sprayed in the circuit modification etching stage is slower than the etching speed of the etchant sprayed in the etching forming etching stage, or, the spray rate of the sprayed etchant of the circuit modification etching stage is smaller than the spray rate of the sprayed etchant of the circuit forming etching stage, and the impact force of the board surface adopted in the circuit modification etching stage is greater than the impact force of the board surface adopted in the circuit forming etching stage, so that the etching speed of the circuit modification etching stage is slower than the etching speed of the circuit forming etching stage; also, the circuit board is horizontally and laterally conveyed, the etchant on the surface of the circuit board is immediately sucked, and the etchant sprayed in the latter section of the circuit modification etching stage is mixed with high-pressure gas; wherein the ratio of the spray amount of the etchant mixed with high pressure gas of the circuit modification etching stage to the total spray amount of the circuit modification etching stage is at least 60%, and the etching stroke of the circuit modification etching stage is 20-100% of the etching stroke of the circuit forming etching stage; whereby, having the effect of improving the etching factor of the circuit board.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A circuit board etching device for improving etching factor, comprising:
a circuit board conveying device, which laterally conveys a circuit board to be etched;
a circuit forming etching tank is arranged in the front section of the circuit board conveying device, and a first etchant spraying unit is arranged relatively to the circuit board conveying device, the first etchant spraying unit sprays a first etchant on the etching surface of the circuit board; and
a circuit modification etching tank is arranged in the rear section of the circuit board conveying device, and a second etchant spraying unit is arranged relatively to the circuit board conveying device, the second etchant spraying unit sprays a second etchant on the etching surface of the circuit board, and make the etching speed of the circuit modification etching tank slower than the etching speed of the circuit forming etching tank.

2. The circuit board etching device for improving etching factor as claimed in claim 1, wherein the etching speed of the second etchant is slower than the etching speed of the first etchant, and make the etching speed of the circuit modification etching tank slower than the etching speed of the circuit forming etching tank; or, the spray flow rate of the second etchant spraying unit is smaller than the spray flow rate of the first etchant spraying unit, and the impact force of the board surface generated by the second etchant spraying unit is greater than the board surface impact force generated by the first etchant spraying unit, so that the etching speed of the circuit modification etching tank is slower than the etching speed of the circuit forming etching tank.

3. The circuit board etching device for improving etching factor as claimed in claim 2, wherein the circuit board conveying device horizontally and laterally conveys the circuit board, the circuit forming etching tank is provided with a first etchant suction unit above the circuit board conveying device, and the circuit modification etching tank is provided with a second etchant suction unit above the circuit board conveying device.

4. The circuit board etching device for improving etching factor as claimed in claim 3, wherein the first etchant spraying unit is provided with a plurality of first etchant spraying nozzles above and below the circuit board conveying device, and the first etchant is pumped from the bottom of the circuit forming etching tank by a first etchant pump, then a first etchant delivery pipe conveys the first etchant to each of the first etchant spraying nozzles; the second etchant spraying unit is provided with a plurality of second etchant spraying nozzles above and below the circuit board conveying device, and the second etchant is pumped from the bottom of the circuit modification etching tank by a second etchant pump, then a second etchant delivery pipe conveys the second etchant to each of the second etchant spraying nozzles; the first etchant suction unit is provided with a plurality of first etchant suction nozzles above the circuit board conveying device, and uses the first etchant pump to make a first ejector of a first etchant suction pipe generates negative pressure, and then the first etchant suction nozzle of the first etchant suction pipe sucks the first etchant on the surface of the circuit board back to the bottom of the circuit forming etching tank; the second etchant suction unit is provided with a plurality of second etchant suction nozzles above the circuit board conveying device, and uses the second etchant pump to make a second ejector of a second etchant suction pipe generates negative pressure, and then the second etchant suction nozzle of the second etchant suction pipe sucks the second etchant on the surface of the circuit board back to the bottom of the circuit modification etching tank.

5. The circuit board etching device for improving etching factor as claimed in claim 4, wherein further make the second etchant spraying nozzle located in the rear section of the circuit modification etching tank adopts a second etchant spraying nozzle mixed with high-pressure gas, and the high-pressure gas of a high-pressure gas source is transported by a high-pressure gas delivery pipe to each second etchant spraying nozzle mixed with high-pressure gas, the second etchant particles are smaller due to the mixing of high-pressure gas and improve the impact force of the board surface.

6. The circuit board etching device for improving etching factor as claimed in claim 5, wherein the ratio of the spray amount of the second etchant mixed with high-pressure gas to the total spray amount of the second etchant is greater than 60%, and the etching stroke of the circuit modification etching tank is 20-100% of the etching stroke of the circuit forming etching tank.

7. A circuit board etching method for improving etching factor which using the device claimed in claim 1, make the circuit board circuit etching process first perform the circuit forming etching stage, then perform the circuit modification etching stage, and the etching speed of the circuit modification etching stage is slower than the etching speed of the circuit forming etching stage.

8. The circuit board etching device for improving etching factor as claimed in claim 7, wherein the etching speed of the etchant sprayed in the circuit modification etching stage is slower than the etching speed of the etchant sprayed in the etching forming etching stage, so that the etching speed of the circuit modification etching stage is slower than the etching speed of the circuit forming etching stage; or, the spray rate of the sprayed etchant of the circuit modification etching stage is smaller than the spray rate of the sprayed etchant of the circuit forming etching stage, and the impact force of the board surface adopted in the circuit modification etching stage is greater than the impact force of the board surface adopted in the circuit forming etching stage, so that the etching speed of the circuit modification etching stage is slower than the etching speed of the circuit forming etching stage.

9. The circuit board etching device for improving etching factor as claimed in claim 8, wherein the circuit board is horizontally and laterally conveyed, the etchant on the surface of the circuit board is immediately sucked, and the etchant sprayed in the latter section of the circuit modification etching stage is mixed with high-pressure gas.

10. The circuit board etching device for improving etching factor as claimed in claim 9, wherein the ratio of the spray amount of the etchant mixed with high pressure gas of the circuit modification etching stage to the total spray amount of the circuit modification etching stage is at least 60%, and the etching stroke of the circuit modification etching stage is 20-100% of the etching stroke of the circuit forming etching stage.
